(19) United States
(12) Patent Application Publication
(10) Pub. No.: US 2016/0276318 A1
(43) Pub. Date: Sep. 22, 2016

(54) Package of LED Chip and Manufacturing Method Thereof

(71) Applicants: Ming SUN, Pudong Shanghai (CN); Jian DAI, Pudong Shanghai (CN); SHANGHAI OPPELLIGHTING CO., LTD., Pudong, Shanghai (CN)

(72) Inventors: Wen-Jung Chuang, Suzhou City (CN); Xing-Bao Chen, Shanghai (CN)

(21) Appl. No.: 14/395,102

(22) PCT Filed: Aug. 15, 2014
(86) PCT No.: PCT/CN2014/084503

§ 371 Date: Oct. 17, 2014

(30) Foreign Application Priority Data
Mar. 12, 2014 (CN) 201410088653.X

(51) Int. Cl. H01L 25/075; H01L 33/48; H01L 33/62; H01L 33/50

(52) U.S. Cl. CPC H01L 25/0753; H01L 33/507; H01L 33/483; H01L 33/62; H01L 2933/0066; H01L 2933/0041; H01L 2933/0033

(57) ABSTRACT

The present invention discloses a package of the LED chip and the related manufacturing method. The present invention is related to the LED package process. The package includes a transparent substrate, the LED chips, conductive wires and so on. The LED chips are installed reversely on the transparent substrate in order to improve the luminous efficiency and to simplify the process procedures.

### BACKGROUND OF THE INVENTION

1. Field of the Invention

The present invention discloses a package of the LED chip and the related manufacturing method, especially related to the LED package process.

2. Descriptions of the Related Art

The LED is a semiconductor converting the electricity into light. The incandescent light is drove via the tungsten and the compact fluorescent light is drove via the RGB fluorescent powder. Unlike the traditional lights, the LED is lightened via an electric field. Comparing the white LED with 5 mm-diameter to the traditional lights such as the incandescent light, the spiral fluorescent light and T5 RGB fluorescent light, the efficiencies of the incandescent light, the spiral fluorescent light, T5 RGB fluorescent light and the LED light are 12 lm/W, 60 lm/W, 96 lm/W and over 150 lm/W respectively; the life times of the incandescent light, the spiral fluorescent light, T5 RGB fluorescent light and the LED light are less than 2000 hrs, less than 8000 hrs, around 10000 hrs and over 10000 hrs respectively.

According to the replacing the incandescent light, the National Development and Reform Commission, the Department of Trade Department of Commerce, the General Administration of Customs, the State Administration for Industry and Commerce and the General Administration of Quality Supervision, Inspection and Quarantine make a joint declaration that the incandescent light is forbidden to be imported and to be sold gradually. The joint declaration states that the traditional incandescent light is forbidden to be imported and to be sold dependent on its power from Oct. 1, 2012.

China is the main country producing and consuming the lightening devices. The productions of the fluorescent light the incandescent light rank first in the world. The total production capacity and the internal sales volume in 2010 are respectively 3.85 billion and 1.07 billion. Roughly speaking, the electricity consumption for lightening devices is estimated to be 12% of the total electricity consumption of the country. Obviously, the high efficient lightening device for replacing the traditional incandescent light shows great potential for its energy-saving ability. It is a great milestone to upgrade the lightening industry, to implement the “10, 2, 5” energy-saving target and to adapt to the global climate via abandonment of the incandescent light. The mature production of the LED lightening is required urgently.

The LED package means that the package of the LED chip which is quite different from the package of the integrated circuit. The LED package is required to protect the chips and to be transparent as well so that the criteria and the property of the package material for LED package are critical.

The method, material, configuration and techniques of the LED package are determined via the structure of the chip, the property of the photoelectricity/mechanism, application, cost and so on. After 40-year developing, the LED package evolves from the lamp LED, SMD LED until the power LED. As the power of the chip grows higher, especially the development of the solid-state lightening, the criterion of optics, thermology, electricity and mechanism become much severer. In order to reduce the thermal resist of the package, a brand new package design must be developed.

Because the configuration and the techniques of the power LED package are complicated and directly affected the performance and the life time, the LED package, especially the white LED package, is always the mainstream of LED developing. The functions for the LED package mainly comprises mechanical protection for higher reliability, heat dissipation for cooling the chip and improving the performance, optical control for increasing the efficiency and optimization of light distribution, power management including AC/DC conversion and power control and so on. How to retain the best performance after packaging is always the main target of the LED researching.

### SUMMARY OF THE INVENTION

In order to overcome the drawbacks in prior art, the present invention discloses a package of a LED chip and the related manufacturing method. First, in order not to block the light from LED chip, select a transparent substrate as the substrate for the LED chip. According to the amounts and the positions of the LED chips exerted, a circuit is sputtered on the transparent substrate and the solder is pasted onto the circuit to install the LED chips to electrically couple the LED chips to the power. That is, the LED chips directly electrically couple to a conductive pattern on the transparent substrate via soldering. The manufacturing method is optimized and the production cost is lower as well. At last, cover a fluorescent gel on the surface of the LEC chip and the surface of the transparent substrate.

The characteristic of the present invention is described as follow.

A manufacturing method of a package of a LED chip includes the following steps: a. select a transparent substrate; b. sputter a conductive pattern having a circuit on the transparent substrate; c. install a LED chip on the conductive pattern via a solder to electrically couple the LED chip and the conductive pattern; and d. cover a fluorescent gel on a surface of the LED chip and a surface of the transparent substrate.

The present invention discloses a method, wherein the transparent substrate includes a sapphire substrate, a glass substrate and a ceramic substrate. The transparent glass substrate is most recommended. Especially, the patterned glass substrate is recommended for better heat dissipation efficiency and better adhesion of the conductive pattern.

The present invention discloses a method, wherein the transparent glass substrate is a patterned transparent glass substrate for providing the better heat dissipation efficiency and the better adhesion of the conductive pattern.

The present invention discloses a method, wherein material of the conductive pattern is selected from ITO, copper, gold, silver, aluminum or a component containing at least two of copper, gold, silver, aluminum. The copper is the better material for conductive pattern due to its good electrical conductivity, good heat dissipation ability and lower cost.

The present invention discloses a method, wherein conductive pattern is made of copper which is sputtered and heated till 200° C. to from an oxide protection layer on the copper conductive pattern. Hence, the copper conductive pattern would not be oxidized or corroded by time and environmental factors in the last few steps of processing or during operation.

The present invention discloses a method, wherein the conductive patterns are electrically isolated at the LED chips.

The present invention discloses a method, wherein the LED chips, which are chip-on-board, are electrically coupled to each other via the conductive pattern.

The present invention discloses a method, wherein the solder exerted for installing the LED chip is pasted on the conductive pattern where an electrode of the LED chip is coupled to. The solder pasted on the electrode can eliminate a height difference between the P/N electrodes and the solder pasted on the conductive pattern and the solder pasted on the electrodes of the LED chip are fused via reflow soldering. Hence, the LED chips would be well-aligned to the transparent substrate.

The present invention also discloses a package of a LED chip. The package includes a transparent substrate, a conductive pattern sputtered on the transparent substrate and a LED chip installed on the conductive pattern and two electrodes of the LED chip are installed on the transparent substrate via a solder and electrically couples to the conductive pattern. Specifically, the LED chip is reversely installed on the transparent substrate. Because the N electrode of the LED chip is formed via etching the chip to expose the N layer inside, obviously, the P electrode and the N electrode of the LED chip are not positioned in the same level. In order to install the LED chip horizontally on to the substrate, the solder is exerted to eliminate the height difference between the P and N electrodes. Also, the solder pasted on the conductive pattern and the solder pasted on the electrodes of the LED chip are fused.

The present invention discloses a package, wherein the transparent substrate includes a sapphire substrate, a glass substrate and a ceramic substrate.

The present invention discloses a package, wherein the transparent substrate is a patterned transparent substrate.

The present invention discloses a package, wherein the conductive patterns sputtered on the transparent substrate are electrically isolated at the LED chips. Especially, the chip is only sputtered in the area corresponding to the electrodes so that the efficiency of the chip can be retained.

The present invention discloses a package, wherein the LED chips are electrically coupled to each other via the conductive pattern.

The present invention discloses a package, wherein the package further includes a fluorescent gel layer covering the LED chips and a surface of the transparent substrate so that the fluorescent powder can be completely excited via the light from the LED chip.

The present invention discloses a package, wherein the LED chip is selected from chip-on-board or flip chip.

The present invention provides a simple package of the LED chip and implements a simple process. The package configuration of the present invention is similar to the traditional COB package configuration but the substrate exerted for COB package is a metal substrate. The transparent substrate exerted in the present invention can achieve the all-angle lightening so that the efficiency is greatly increased. Moreover, the conductive pattern of the present invention is directly sputtered on to the transparent substrate to electrically couple to the chips. Via the solder, the electrodes of the LED chip are pasted and electrically coupled to the conductive pattern. No more gold wire has to be bonded in the present invention so that the process is simplified and the cost is down.

### BRIEF DESCRIPTION OF THE DRAWINGS

FIG. 1 illustrates the cross-section view of a package of a single LED chip of the present invention.

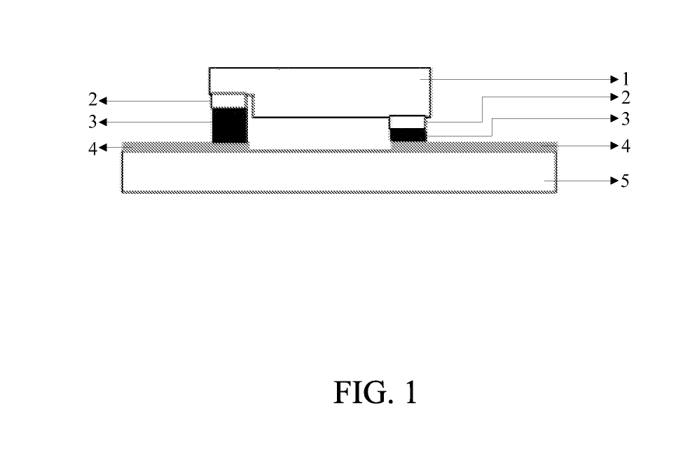

FIG. 2 illustrates the partial cross-section view of a package of a LED chip of the present invention.

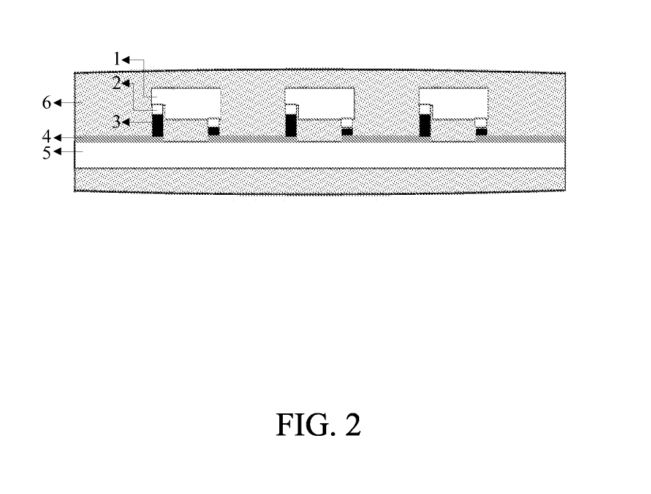

FIG. 3 illustrates the top view of a package of a sheet LED chip of the present invention.

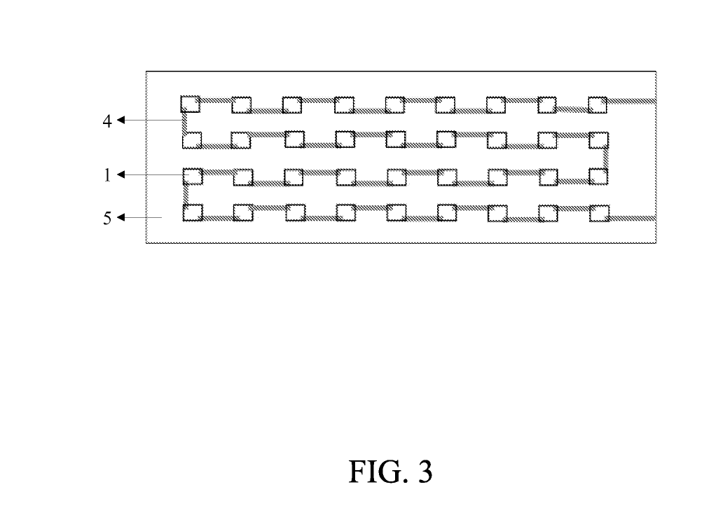

FIG. 4 illustrates the top view of a package of a thread LED chip of the present invention.

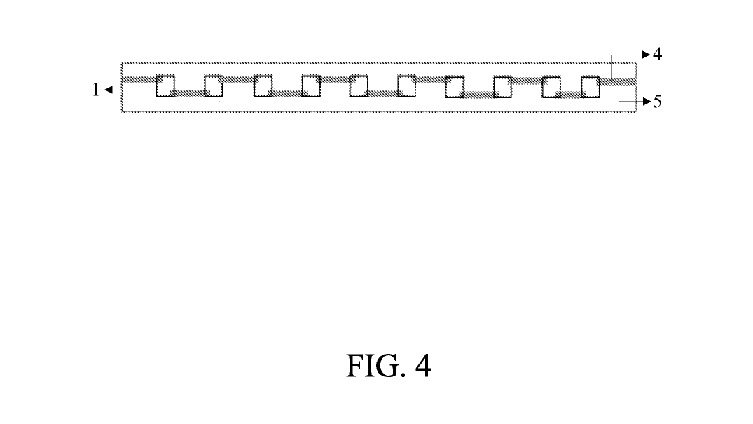

### EXPLANATIONS OF LETTERS OR NUMERALS

1 LED chip
2 electrode of the LED chip
3 solder
4 conductive pattern
5 transparent substrate
6 fluorescent gel layer

### DESCRIPTION OF THE PREFERRED EMBODIMENT

### Embodiment

The LED chips may be classified into the chip-on-board (COB) chip and the flip chip, wherein the flip chip is developed for overcome the drawbacks of COB chip. Although, the efficiency of the COB chip is increased recently; the procedures of manufacturing the flip chip are complicated and difficult to process so that the cost is high. In the present invention, the substrate is transparent, the conductive pattern is directly sputtered on the transparent substrate and the COB LED chips are directly pasted onto the conductive pattern. Accordingly, the efficiency of the packed COB LED chip of the present invention can be the same with efficiency of the traditional flip chip. The present invention can increase the efficiency of the packed COB chip, simplify the procedures and lower the cost.

In order not to block the light from LED chip, select a transparent substrate as the substrate for the LED chip. Select the COB LED chips 1. According to the amounts and the positions of the LED chips 1 exerted, a copper conductive pattern is sputtered on the transparent substrate and keep heating the copper conductive pattern up to 200° C. to form an oxide protection layer. Paste the solder 3 onto the copper conductive pattern. To ensure that the LED chips 1 can be well-aligned to the transparent substrate, the solder 3 exerted for installing the LED chip 1 is pasted on the conductive pattern where an electrode 2 of the LED chip 1 is coupled to. The solder 3 pasted on the electrode 2 can eliminate a height difference between the P/N electrodes 2. The solder 3 pasted on the conductive pattern and the solder 3 pasted on the electrodes 2 of the LED chip 1 are fused via reflow soldering. Hence, the LED chips 1 and the conductive pattern 4 are pasted and electrically coupled. At last, cover the fluorescent gel layer 6 on the surface of the transparent substrate 5 and complete the package process.

The above embodiments merely give the detailed technical contents of the present invention and inventive features thereof, and are not to limit the covered range of the present invention. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

1. A manufacturing method of a package of a LED chip includes the following steps:
a. select a transparent substrate,
b. sputter a conductive pattern having a circuit on said transparent substrate,
c. install a LED chip on said conductive pattern via a solder to electrically couple said LED chip and said conductive pattern, and
d. cover a fluorescent gel on a surface of said LED chip and a surface of said transparent substrate.

2. The manufacturing method of a package of a LED chip of claim 1, wherein said transparent substrate includes a sapphire substrate, a glass substrate and a ceramic substrate.

3. The manufacturing method of a package of a LED chip of claim 2, wherein said transparent substrate is a patterned transparent substrate.

4. The manufacturing method of a package of a LED chip of claim 1, wherein material of said conductive pattern is selected from ITO, copper, gold, silver, aluminum or a component containing at least two of copper, gold, silver, aluminum.

5. The manufacturing method of a package of a LED chip of claim 1, wherein said conductive pattern is made of copper which is sputtered and heated till 200° C. to from an oxide protection layer on said conductive pattern.

6. The manufacturing method of a package of a LED chip of claim 1, wherein said conductive patterns are electrically isolated at said LED chips.

7. The manufacturing method of a package of a LED chip of claim 6, wherein said LED chips, which are chip-on-board, are electrically coupled to each other via said conductive pattern.

8. The manufacturing method of a package of a LED chip of claim 1, wherein said solder exerted for installing said LED chip is pasted on said conductive pattern where an electrode of said LED chip is coupled to and said solder pasted on said electrode can eliminate a height difference between said P/N electrodes and said solder pasted on said conductive pattern and said solder pasted on said electrodes of said LED chip are fused via reflow soldering.

9. A package of a LED chip includes a transparent substrate, a conductive pattern sputtered on said transparent substrate and a LED chip installed on said conductive pattern and two electrodes of said LED chip are installed on said transparent substrate via a solder and electrically couples to said conductive pattern.

10. The package of a LED chip of claim 9, wherein said transparent substrate includes a sapphire substrate, a glass substrate and a ceramic substrate.

11. The package of a LED chip of claim 10, wherein said transparent substrate is a patterned transparent substrate.

12. The package of a LED chip of claim 9, wherein said conductive patterns sputtered on said transparent substrate are electrically isolated at said LED chips.

13. The package of a LED chip of claim 12, wherein said LED chips are electrically coupled to each other via said conductive pattern.

14. The package of a LED chip of claim 9, further includes a covering said LED chips and a surface of said transparent substrate.

15. The package of a LED chip of claim 9, wherein said LED chip are selected from chip-on-board or flip chip.

16. The package of a LED chip of claim 10, further includes a covering said LED chips and a surface of said transparent substrate.

17. The package of a LED chip of claim 11, further includes a covering said LED chips and a surface of said transparent substrate.

18. The package of a LED chip of claim 12, further includes a covering said LED chips and a surface of said transparent substrate.

19. The package of a LED chip of claim 13, further includes a covering said LED chips and a surface of said transparent substrate.
